(19) United States
(12) Patent Application Publication
(10) Pub. No.: US 2007/0104337 A1
(43) Pub. Date: May 10, 2007

(54) Apparatus and method for automatic volume synchronization of a digital audio device with an analog audio source

(76) Inventors: Gregory R. Shurtz, Houston, TX (US); Thanh T. Tran, Houston, TX (US); Rishi Bhattacharya, Houston, TX (US)

Correspondence Address: TEXAS INSTRUMENTS INCORPORATED, P O BOX 655474, M/S 3999, DALLAS, TX, 75265, US

(21) Appl. No.: 11/268,895

(22) Filed: Nov. 8, 2005

(51) Int. Cl. H03G 3/00; G06F 17/00

(52) U.S. Cl. 381/104; 381/107; 700/94

(57) ABSTRACT

In audio source device the provides a digitized audio signal without volume information, apparatus is coupled to the analog audio conductors to determine the amplitude of the analog signals and therefore the volume of the resulting from the application of the analog audio signals to output apparatus such as speakers. The determination of the amplitude of the analog signals provides indicia of the volume resulting from the analog signals. This amplitude is then digitized and combined with the audio digital signal being transported. The output resulting from the playing of the digitized audio signals can in this manner have a volume dependence that is consistent with the volume of the analog audio signals.

### BACKGROUND OF THE INVENTION

1. Field of the Invention

This invention relates generally to systems and, more particularly, to audio systems in which an audio source device provides a signal to a digital speaker system.

2. Background of the Invention

Many commercial audio sources (e.g., home stereo receivers) can, in addition to audio signals with a volume control, provide digital audio output signals that may be used to provide digitalized version of the audio signal. The digitized audio signal lacks the information to provide volume control.

The problem arises for implementing devices such as digital speakers that would utilize the digital audio output signals because such a device would require a separate volume control, the volume control not automatically synchronized with the volume setting of the audio source device itself. An example of the dilemma is the Bluetooth or IEE 802.11 wireless LAN wireless rear speakers for a surround sound audio system. Such speakers could be implemented using the digital audio output signal from a consumer receiver, but separate volume control on the speakers would be inconvenient for the end user.

A need has therefore been felt for apparatus and an associated method having the feature of providing an improved audio source. It would be another feature of the apparatus and associated method to provide an improved digital signal from and audio source. It would be yet another feature of the apparatus and associated method to provide for control of the volume of the digital signal produced by an audio source. It would be a still further feature of the apparatus and associated method to provide a digital signal having a volume related to the volume of an associated analog signal.

### SUMMARY OF THE INVENTION

The foregoing and other features are accomplished, according the present invention, by providing apparatus monitoring the analog signals that are generated by an audio source. The volume of the audio from speakers will be determined by the amplitude of the analog signals which vary with the volume control at the receiver end. The amplitude of the audio analog signals and peak is detected then digitized. The analog signal volume amplitude determines the amplitude of the digitized signals thereby relating the digitized signal audio volume to the analog signal audio volume.

Other features and advantages of present invention will be more clearly understood upon reading of the following description and the accompanying drawings and the claims.

### BRIEF DESCRIPTION OF THE DRAWINGS

FIG. 1 is a block diagram of apparatus for controlling the volume of an audio digital signal produced by an analog source device according to the present invention.

FIG. 2 is a block diagram of apparatus for controlling the volume of an audio digital signal with specific reference to the Bluetooth technology or IEEE 802.11 wireless LAN technology according to the present invention.

### 1. DETAILED DESCRIPTION OF THE FIGURES

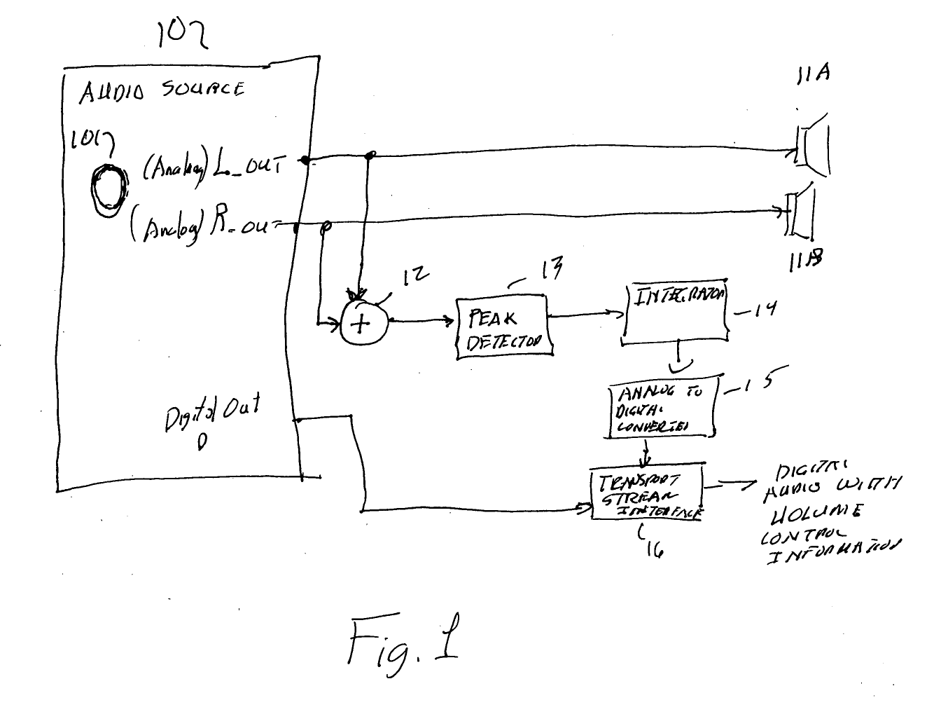

Referring to FIG. 1, the apparatus for controlling the volume of an audio digital signal generated by an audio source 10 is shown. The audio source 10 provides (L-out and R-out) analog audio signals to two speakers 11A and 11B. A summing unit 12 is coupled to the conductors carrying the two analog audio analog signals to speakers 11A and 11B. The output signal from the summing unit 12 is applied to peak detector 13. The output signal of peak detector 13 is applied to integrator 14. The output signal of the integrator 14 is applied to analog to digital converter 15. A transport stream interface unit 16 receives a stream of digital output signals from the audio source 10 and a digital volume control signal from the analog to digital converter 15. The signal from the analog to digital converter 15 is used to control the volume of the digital audio signal.

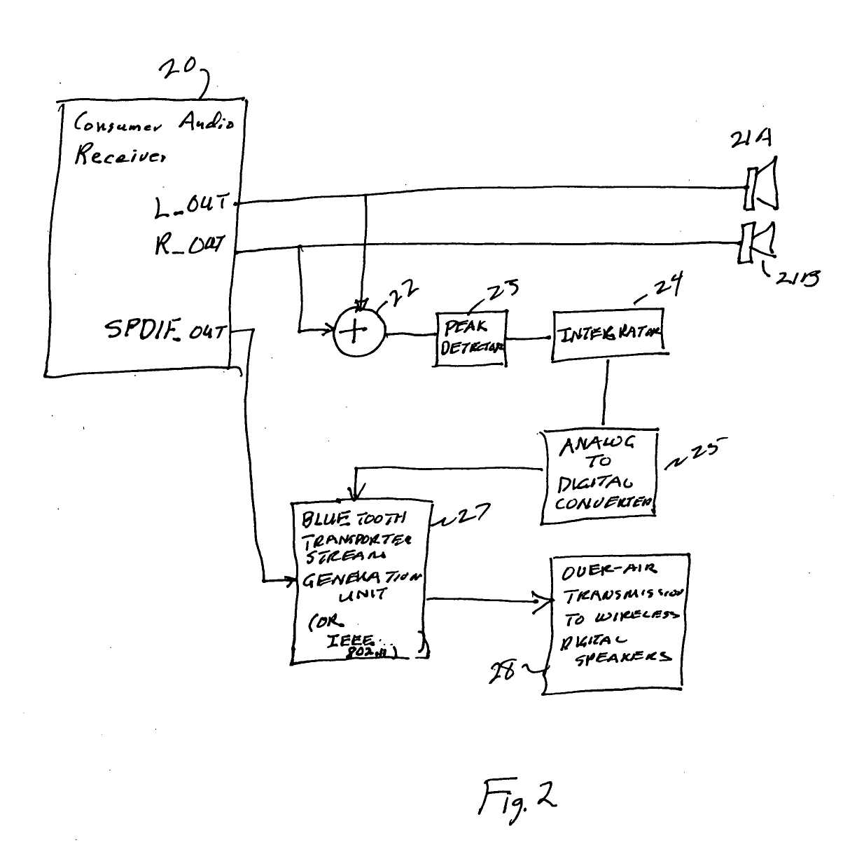

Referring to FIG. 2, a block diagram of the apparatus to control a digital audio signal with specific reference to Bluetooth or IEEE 802.11 wireless LAN technology is shown. A consumer audio receiver applies analog audio L_OUT signals to speaker 21A and analog audio R_OUT signals to speaker 21B. The conductors carrying the L_OUT and the R_OUT signals are each coupled to input terminals of a summing unit 22. The output signal of the summing unit 22 is applied to a peak detector 23. The output signal of the peak detector 23 is coupled to an input terminal of integrator 24. The output terminal of integrator 24 is coupled to an input terminal of analog to digital logic 25. The output signal of the analog to digital converter 25 is applied to the Bluetooth or IEEE 802.11 transport stream generation logic 27. The Bluetooth or IEEE 802.11 transport stream generation logic 27 also receives the SPDIF_OUT signal from the consumer audio receiver 20. The output signal from the Bluetooth or IEEE 802.11 transport stream generation unit 27 is applied to the RF transmitter. The output signal from the RF transmitter 28 is the over the air transmission to the wireless digital speaker.

### 2. OPERATION OF THE PREFERRED EMBODIMENT

The operation of the present invention can be understood as follows. The analog output signal of the audio source is processed by the summing network; the peak detector and the integrator provide a value that is related to the average amplitude of the signal in the two channels of the audio source output. The analog to digital device then periodically digitizes this average amplitude. The digitized value can be used in two ways. In the first method, the digitized amplitude signals are incorporated in the transported signal. The incorporated signals can then be analyzed by the apparatus receiving the signals and the volume of the output audio signal derived from the transported signal adjusted to be consistent with analog audio signals. Another technique for controlling the volume of the digitized audio signals is to use the amplitude derived from the analog audio signals to determine the strength of the transported digital signal, the changes in the amplitude of the transported signal being used to determine the volume of the digital audio signals resulting from the transported signals.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

What is claimed is:

1. In an audio source device providing analog audio signals and digitized audio signals, apparatus for providing the digitized audio signals with volume information, the apparatus comprising:
a network coupled to analog audio signal output terminals, the network providing an average value of the analog audio signals;
a digitizing unit for converting the average value of the analog audio signals to digital values; and
a combining network, the combining network combing the digital audio signals with the digital values to control the volume of the audio output resulting from digital audio signals.

2. The apparatus as recited in claim 1 wherein the audio output resulting from the digital analog signals is related to the audio output resulting from the analog audio signals.

3. The apparatus as recited in claim 1 wherein the network includes:
a summing unit coupled to the analog audio signal output terminals;
a peak detector coupled to the summing unit; and
an integrator coupled to the peak detector.

4. The apparatus as recited in claim 1 wherein the digitizing unit is an analog to digital converter.

5. The apparatus as recited in claim 1 wherein the digitized audio signals are transported to external audio output units.

6. The apparatus as recited in claim 1 wherein the digitized audio signals are Bluetooth or IEEE 802.11 compatible digital signals.

7. The apparatus as recited in claim 1 wherein the amplitude of the audio signals is controllable.

8. A method of providing volume control for digitized signals transported from an audio source, the method comprising:
determining a value for amplitude of analog audio signals generated by the audio source;
digitizing the value of the amplitude; and
using the digitized value of the amplitude to control the volume of the digitized signals.

9. The method as recited in claim 8 wherein the determining includes:
applying the analog audio signals to a peak detector; and
applying the output signals of the peak detector to an integrator.

10. The method as recited in claim 8 wherein the analog audio signals are generated in two channels, the method further including applying the analog audio signals to a summing unit before applying the analog audio signal to the peak detector.

11. The method as claim 8 further including:
generating Bluetooth or IEEE 802.11 audio signals in the audio source; and
combining the digitized value of the amplitude with the Bluetooth signals in a Bluetooth or IEEE 802.11 transport stream generation unit.

12. The method as recited in claim 8 further includes controlling the amplitude of the analog audio signals.

13. An audio system, the system comprising:
an audio source generating analog audio signals and digital audio signals;
a first audio output unit coupled to the audio source; the audio output unit providing a audio output for the analog audio signals;
an amplitude detector for determining the amplitude of the analog audio signals;
a transport unit for transporting the digital audio signals to a second audio output unit, the transport unit responsive to the amplitude for controlling the volume of the digital audio output.

14. The system as recited in claim 13 wherein the amplitude is controllable.

15. The system as recited in claim 13 wherein the digital audio signals are Bluetooth or IEEE 802.11 compatible signals.

16. The system as recited in claim 13 wherein the amplitude detector provides a digitzed value of the amplitude.
